(19) United States
(12) Patent Application Publication
(10) Pub. No.: US 2024/0290730 A1
(43) Pub. Date: Aug. 29, 2024

(54) DIE BENDING STIFFNESS MODIFICATION THROUGH GROOVING

(71) Applicant: International Business Machines Corporation, Armonk, NY (US)

(72) Inventors: Sathyanarayanan Raghavan, Ballston Lake, NY (US); Mukta Ghate Farooq, HOPEWELL JCT, NY (US); Prabudhya Roy Chowdhury, Albany, NY (US)

(21) Appl. No.: 18/175,985

(22) Filed: Feb. 28, 2023

(51) Int. Cl. H01L 23/00; H01L 21/304; H01L 23/053; H01L 25/065

(52) U.S. Cl. CPC H01L 23/562; H01L 21/3043; H01L 23/053; H01L 25/0657

(57) ABSTRACT

A semiconductor structure for tailoring a die stiffness. The semiconductor structure may include a packaging substrate, a lid, and a first semiconductor die between the packaging substrate and the lid. The first semiconductor die may have a frontside attached to the packaging substrate that has semiconductor devices. The first semiconductor die may also have a backside, opposite the frontside, that has grooves less than a thickness of the first semiconductor die.

### BACKGROUND

The present invention relates generally to the field of semiconductor device packaging, and more particularly to cutting grooves on the backside of a semiconductor device die to reduce the bending stiffness of the packaging.

Semiconductor device fabrication is the process used to manufacture semiconductor devices, typically integrated circuit (IC) “chips” such as computer processors, microcontrollers, and memory chips such as NAND flash and dynamic random-access memory (DRAM) that are present in everyday electrical and electronic devices. The fabrication is a multiple-step sequence of photolithographic and physico-chemical processing steps (such as thermal oxidation, thin-film deposition, ion-implantation, and etching) during which electronic circuits are gradually created on a wafer typically made of pure single-crystal semiconducting material. Silicon is almost always used, but various compound semiconductors are used for specialized applications.

The fabrication process is performed in highly specialized semiconductor fabrication plants, also called foundries or fabs, with the central part being the clean room. Production in advanced fabrication facilities is completely automated and carried out in a hermetically sealed nitrogen environment to improve yield (i.e., the percent of microchips that function correctly in a wafer), with automated material handling systems taking care of the transport of wafers from machine to machine. Flip chip is a method for interconnecting dies such as semiconductor devices, IC chips, integrated passive devices and microelectromechanical systems (MEMS), to external circuitry with solder bumps that have been deposited onto the chip pads. The solder bumps are deposited on the chip pads on the top side of the wafer during the final wafer processing step. In order to mount the chip to external circuitry (e.g., a circuit board or another chip or wafer), it is flipped over so that its top side faces down, and aligned so that its pads align with matching pads on the external circuit, and then the solder is reflowed to complete the interconnect. This is in contrast to wire bonding, in which the chip is mounted upright and fine wires are welded onto the chip pads and lead frame contacts to interconnect the chip pads to external circuitry.

The flip chip method of interconnecting dies can sometimes cause the semiconductor dies packaged within the package to expand at a different rates due to the different coefficients of thermal expansion. This difference can result in breakage, ruining the package or die, or warping of the die. A need exists, therefore, to prevent the catastrophic failures such as cracking of the die, cracking in thin-film dielectric layers deposited on the silicon die, die chipping, electrical failure, solder bump cracking, etc. that result from the differences in expansion caused by the current methods of interconnecting dies.

### SUMMARY

In one aspect, the present invention provides a semiconductor structure with increased flexibility to prevent stress-related defects like cracking and bending. The semiconductor structure may include a packaging substrate, a lid, and a first semiconductor die between the packaging substrate and the lid. The first semiconductor die may have a frontside attached to the packaging substrate that has semiconductor devices. The first semiconductor die may also have a backside, opposite the frontside, that has grooves less than a thickness of the first semiconductor die. The grooves may be patterned after a groove pattern that provides the first semiconductor structure with flexibility in certain areas, without sacrificing strength.

In certain embodiments, the grooves may include optional first parallel grooves along a first direction and/or second parallel grooves along a second direction. The parallel grooves (in the first or second direction) may be formed in perpendicular directions to facilitate consistent and repeatable fabrication. The grooves are not required to be present over the entire first semiconductor die, but certain embodiments may include a clean region without grooves. The clean region may be in a location of the semiconductor die that does not require enhanced flexibility. The clean region may be fabricated by including grooves of different lengths.

In certain embodiments, the grooves may include a depth that is greater than half of the thickness of the semiconductor die. Additional depths may be customized to the groove pattern as well. The depth of the grooves provides the flexibility to withstand expansion stresses without fully and painstakingly thinning the entire semiconductor die. In certain embodiments, the semiconductor die may be thinned, though, and the thinning may be varied such that the thickness varies across the semiconductor die. This varied thickness compliments the groove pattern to increase flexibility and resistance to stresses across the semiconductor structure.

The grooves may differ in any number of characteristics. For example, in certain embodiments, the grooves may include a first groove and a second groove with a difference between the first groove and the second groove selected from the group consisting of: a length, a width, and a depth. The advantage for using different lengths, widths, and depths is that different parts of the die may benefit from different amounts of flexibility, and the effort required to provide that flexibility may be tailored to those areas rather than uniformly applying unnecessary flexibility to the entire die.

In another aspect, the present invention provides a method of fabricating a semiconductor structure. The method may include fabricating semiconductor devices on a frontside of a first semiconductor die, and cutting grooves in a backside of the first semiconductor die opposite the frontside, according to a groove pattern. The groove pattern may be selected to increase flexibility in the first semiconductor die. The groove pattern may be designed to increase flexibility in particular areas of the semiconductor die, such as the corners. The cutting of the grooves may further include rounding edges off the grooves, which can soften the edges and decrease the defects due to errant snags.

In yet another aspect, the present invention provides a semiconductor structure. The semiconductor structure may include a semiconductor die. The die may be fabricated with a first section with first grooves cut into a backside of the semiconductor die, a second section comprising second grooves cut into the backside of the semiconductor die, and a clean region comprising no grooves. The grooves provide the benefit of fewer defects by increasing flexibility in the semiconductor die. The increased flexibility means that the semiconductor die is less likely to crack, bend, or otherwise suffer permanent defect due to differing expansion rates between components of the semiconductor structure.

### BRIEF DESCRIPTION OF THE SEVERAL VIEWS OF THE DRAWINGS

FIG. 1 cross-sectional perspective view of a semiconductor structure, in accordance with one embodiment of the present invention.

FIG. 2 depicts a cross-sectional perspective view of a semiconductor structure, in accordance with one embodiment of the present invention.

FIG. 3 depicts a cross-sectional perspective view of a semiconductor die, in accordance with one embodiment of the present invention.

FIG. 4 depicts a cross-sectional perspective view of a semiconductor die, in accordance with one embodiment of the present invention.

FIG. 5 depicts a cross-sectional side view of a portion of a semiconductor die, in accordance with one embodiment of the present invention.

FIG. 6 depicts a cross-sectional side view of a portion of a semiconductor die, in accordance with one embodiment of the present invention.

FIG. 7 depicts a cross-sectional side view of a semiconductor die, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

Technical measures to solve the issue of integrated circuit manufacturing have included fabricating a semiconductor die with transistors embedded within a silicon substrate, and then packaging the semiconductor die within a package, which includes mounting the die, connecting die pads to pins on the package, and sealing the die. With integrated circuits (ICs) developing with ever-increasing numbers of transistor cells with smaller tolerances and thinner structural support, it is inevitable that the ICs and packaging may produce defects due to the variability in the forces between the various components. For example, during testing and operation of the ICs, the packaging components may expand at one coefficient of thermal expansion, while the semiconductor dies packaged within the package may expand at a different coefficient. This difference can result in breakage, ruining the package or die, or warping of the die. Such a package consists of different materials with varying mechanical properties interacting with each other. For example, during reliability testing to assess the lifetime of the packages, the packages are subjected to thermal excursions. During the testing, the substrate expands at a different rate compare the die due to differing coefficient of thermal expansion between the materials. This relative motion can result in catastrophic failures such as cracking of the die, cracking in thin-film dielectric layers deposited on the silicon die, die chipping, electrical failure, solder bump cracking, etc. The embodiments described herein recognize that stresses caused by varying forces can be mitigated by cutting grooves in a backside of a semiconductor die. The grooves increase flexibility of the semiconductor die, without requiring a time-consuming and delicate die thinning process.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Each reference number may refer to an item individually or collectively as a group. For example, groove 220 may refer to a single groove 220 or multiple grooves 220.

The present invention will now be described in detail with reference to the Figures.

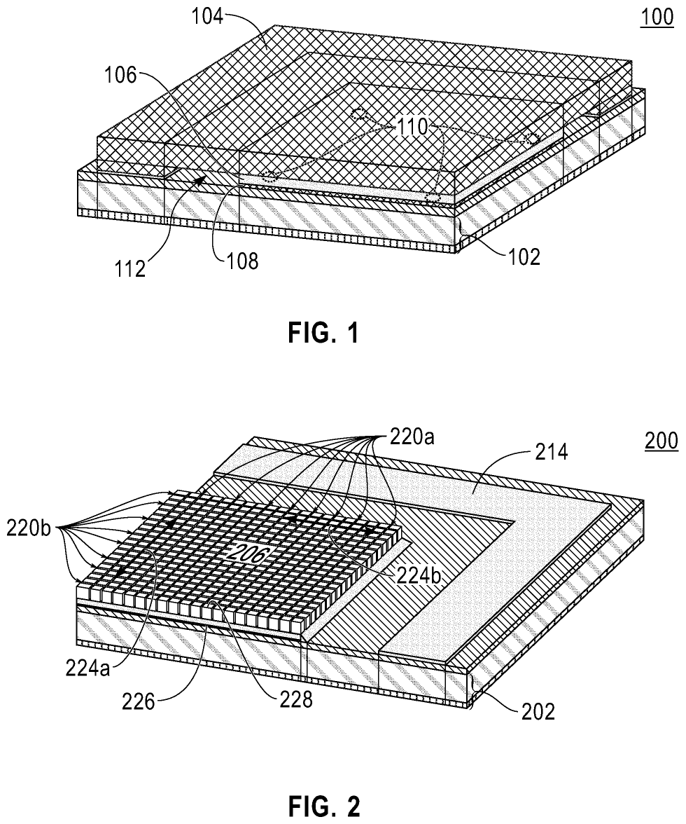

FIG. 1 depicts a cross-sectional perspective view of a semiconductor structure 100, in accordance with one embodiment of the present invention. The semiconductor structure 100 includes a packaging substrate 102, a lid 104, a top die 106, and a bottom die 108. In certain embodiments, the semiconductor structure 100 may include only one die, other embodiments may include more than the two dies 106, 108 shown in FIG. 1. The top die 106 and the bottom die 108 may include active devices fabricated within the die 106, 108, for example on a face (e.g., top face or bottom face). In certain embodiments, the bottom die 108 may be thinned so that the active devices include components on both faces. For example, the bottom die 108 may be thinned to a thickness of 10-50 μm before being fixed in place. The top die 106 and bottom die 108 may be bonded together (e.g., hybrid bonded using copper pads) before being installed together on the packaging substrate 102.

The active devices are connected to the packaging substrate 102 so that signals may be conveyed to and from electrical components external to the semiconductor structure 100. The connection to the packaging substrate 102 may include solder bumps 110, for example. The semiconductor structure 100 may also include an airgap 112 around the dies 106, 108 due to the difference between the size of the lid 104 and the dies 106, 108.

The assembled semiconductor structure 100 often experiences high temperature fluctuations (including during testing) that, as mentioned above, can cause breaks or stresses within the dies 106, 108. Specifically, the lid 104, the packaging substrate 102, and the dies 106, 108 have different coefficients of thermal expansion, so that changes in temperature can strain the connections between the lid 104, the packaging substrate 102, and the dies 106, 108. To mitigate the strain, the top die 106 includes grooves cut into a backside (opposite from the fabricated devices) that increase flexibility of the die and thus improve resiliency of the top die 106 during thermal expansion of the semiconductor structure 100, and during other stresses on the top die 106.

FIG. 2 depicts a cross-sectional perspective view of a semiconductor structure 200 with a top die 206 attached to a bottom die 208 and a packaging substrate 202, in accordance with one embodiment of the present invention. The semiconductor structure 200 is shown without a lid, but the packaging substrate 202 includes a seal band 214 (e.g., adhesive) to secure the lid (e.g., lid 104) into place. The semiconductor die 206 includes first grooves 220a that are parallel along a first direction 224a, and second grooves 220b that are parallel along a second direction 224b. In FIG. 2, the first direction 224a is perpendicular to the second direction 224b, but (as illustrated below) one sets of grooves (e.g., first grooves 220a) may align with a different set grooves (e.g., second grooves 220b) at non-square angles as well. The first grooves 220a are also uniform in other groove characteristics such as pitch, depth, and width, but, in certain embodiments, these and other groove characteristics may vary the first grooves 220a, and may vary from the first grooves 220a to the second grooves 220b.

The top die 206 may be fabricated and the grooves 220a, b cut before packaging within the semiconductor structure 200. That is, on a frontside 226 (i.e., behind and not visible in FIG. 2) semiconductor devices are fabricated according to any known fabrication processes. The top die 206 may then, in certain embodiments, be thinned. The thinning of the top die 206 may be completed uniformly or non-uniformly. In a uniform thinning, the top die 206 has the entire backside 228 (opposite the frontside 226) thinned down by a specific amount. This type of thinning can be useful in providing flexibility to the top die 206, but can be expensive and time-consuming to complete accurately. Non-uniform thinning causes the top die 206 to be thinner in some locations and thicker in other locations (see FIG. 7 and accompanying description below). The non-uniform thinning can provide extra flexibility to high-stress portions of the top die 206 without the precision required for uniform thinning.

After device fabrication and potential thinning of the top die 206, the top die 206 may then have the grooves 220a, b cut into the backside 228 according to a groove pattern. The groove pattern defines the characteristics (e.g., angles, depth, pitch, width) of first grooves 220a, second grooves 220b, and third or fourth grooves, etc. The groove pattern may be iterated and developed for specific die assemblies and semiconductor structures 100, 200 to increase flexibility and yield due to decreases in stress-related defects. The grooves 220a, b may be cut using mechanical dicing saws, laser dicing, reactive ion etching, plasma dicing, chemical etching or other methods to partially cut through the top die 206. The grooves 220a, b may then be softened (i.e., have sharp edges removed or rounded) using a plasma dicing or other etching process.

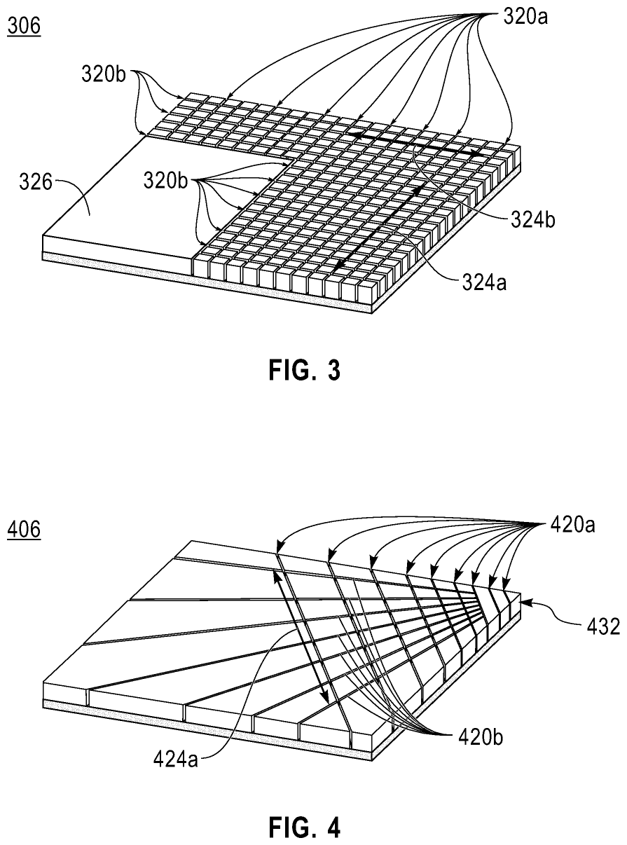

FIG. 3 depicts a cross-sectional perspective view of a semiconductor die 306, in accordance with one embodiment of the present invention. The semiconductor die 306 includes first grooves 320a that are parallel along a first direction 324a, second grooves 320b that are parallel along a second direction 324b. The first direction 324a and the second direction 324b are perpendicular as with the semiconductor die 206 of FIG. 2. The semiconductor die 306 of FIG. 3, however, also includes a clean region 326 that does not contain any of the first grooves 320a or the second grooves 320b. In other words, a length of the grooves 320a, b may extend only partially across the semiconductor die 306, or may extend fully across the semiconductor die 306. In FIG. 3, the grooves 320a, b extend a uniform length across the semiconductor die 306, but in certain embodiments the grooves 320a, b may vary in length, such that some grooves 320a, b extend further across the semiconductor die 306 than other grooves 320a, b.

FIG. 4 depicts a cross-sectional perspective view of a semiconductor die 406, in accordance with one embodiment of the present invention. The semiconductor die 406 includes first grooves 420a that are parallel along a first direction 424a, and second grooves 420b that are not parallel, but vary in angle relative to the first grooves 420a and to others of the second grooves 420b. The second grooves 420b converge on a corner 432 of the semiconductor die 406, which may provide better flexibility to the corner 432 for some examples of the semiconductor die 406.

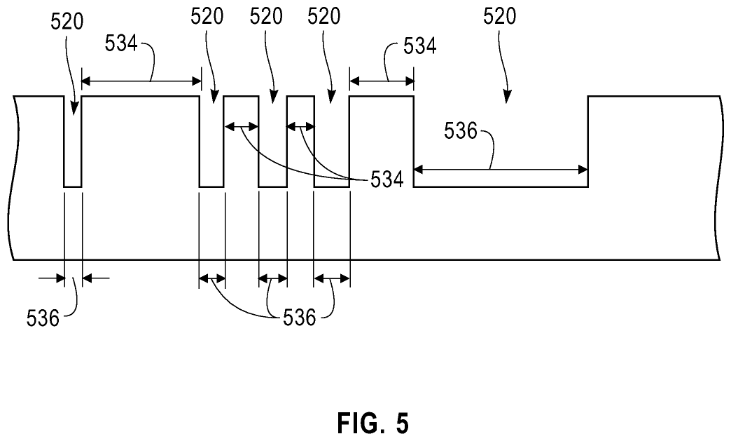

FIG. 5 depicts a cross-sectional side view of a portion of a semiconductor die 506, in accordance with one embodiment of the present invention. The semiconductor die 506 includes grooves 520. The grooves 520 in this embodiment of the semiconductor die 506 do not have a visible directional angle (as the figure is only one cross-sectional view), but the view illustrates that the grooves 520 vary in pitch and in width. That is, distances 534 between the grooves 520 vary, even potentially in embodiments where the grooves 520 are parallel. A width 536 of the grooves 520 can also vary depending on the flexibility required for the semiconductor die 506.

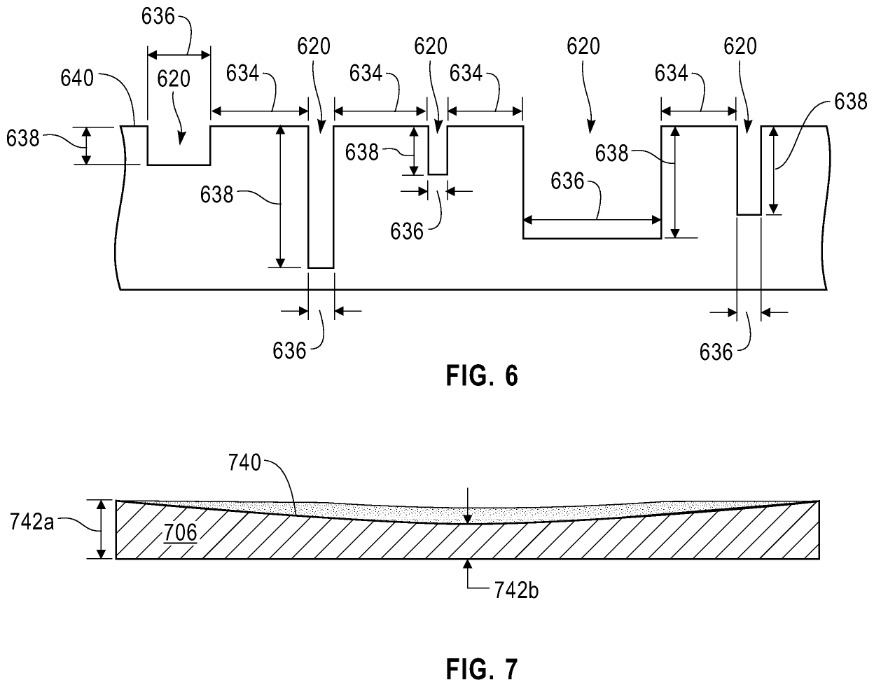

FIG. 6 depicts a cross-sectional side view of a portion of a semiconductor die 606, in accordance with one embodiment of the present invention. The semiconductor die 606 includes grooves 620. The grooves 620 in this embodiment of the semiconductor die 606 do not have a visible directional angle (as the figure is only one cross-sectional view), but the view illustrates that the grooves 520 vary in pitch, width, and depth. That is, distances 634 between the grooves 620, a width 636 of the grooves 520, and also a depth 638 below a top surface 640 can also vary depending on the flexibility required for the semiconductor die 506.

FIG. 7 depicts a cross-sectional side view of a semiconductor die 706, in accordance with one embodiment of the present invention. The semiconductor die 706 is shown at a step in the fabrication process before any grooves are cut, but after a thinning process has created a non-uniform top surface 740. The thinned semiconductor die 706 includes a first thickness 742a that is bigger than a second thickness 742b. The semiconductor die 706 may be thinned using a number of techniques such as chemical-mechanical polishing, etching, or other thinning methods. The center of the semiconductor die 706 may thus be thinned more than the edges of the semiconductor die 706 so that the center is thinned down to the second thickness 742b.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a packaging substrate;
a lid; and
a first semiconductor die between the packaging substrate and the lid, comprising:
a frontside packaged toward the packaging substrate, comprising semiconductor devices; and
a backside, opposite the frontside, comprising grooves less than a thickness of the first semiconductor die.

2. The semiconductor structure of claim 1, wherein the grooves comprise first parallel grooves along a first direction.

3. The semiconductor structure of claim 2, wherein the grooves comprise second parallel grooves along a second direction.

4. The semiconductor structure of claim 3, wherein the first direction is perpendicular to the second direction.

5. The semiconductor structure of claim 1, wherein the backside comprises a clean region without the grooves.

6. The semiconductor structure of claim 1, wherein the grooves comprise a depth that is greater than half of the thickness of the semiconductor die.

7. The semiconductor structure of claim 1, wherein the grooves comprise a varying pitch between the grooves.

8. The semiconductor structure of claim 1, wherein the thickness of the semiconductor die varies across the semiconductor die.

9. The semiconductor structure of claim 1, wherein the grooves comprise a first groove and a second groove with a difference between the first groove and the second groove selected from the group consisting of: a length, a width, and a depth.

10. The semiconductor structure of claim 1, further comprising a second semiconductor die between the first semiconductor die and the packaging substrate.

11. A method, comprising:
fabricating semiconductor devices on a frontside of a first semiconductor die; and
cutting grooves in a backside of the first semiconductor die opposite the frontside, according to a groove pattern.

12. The method of claim 11, wherein the grooves comprise first parallel grooves cut in parallel lines along a first direction.

13. The method of claim 11, wherein cutting the grooves comprises utilizing a process selected from the group consisting of: mechanical dicing, plasma dicing, and laser dicing.

14. The method of claim 11, further comprising rounding edges of the grooves.

15. The method of claim 11, wherein cutting the grooves comprises varying the pitch between the grooves.

16. A semiconductor structure, comprising:
a semiconductor die, comprising:
a first section comprising first grooves cut into a backside of the semiconductor die;
a second section comprising second grooves cut into the backside of the semiconductor die; and
a clean region comprising no grooves.

17. The semiconductor structure of claim 16, comprising a difference between the first grooves and the second grooves, wherein the difference is selected from the group consisting of: depth of the grooves, pitch of the grooves, angle of the grooves, length of the grooves, width of the grooves, and curve of the grooves.

18. The semiconductor structure of claim 16, further comprising additions to the first section, wherein a thickness of the first section is different from a thickness of the second section.

19. The semiconductor structure of claim 18, wherein the additions comprise a selection from the group consisting of: cubes cut from another die and strips cut from another die.

20. The semiconductor structure of claim 16, wherein the first grooves comprise a depth that is greater than half of a thickness of the semiconductor die.
